(19) United States
(12) Patent Application Publication
(10) Pub. No.: US 2026/0271651 A1
(43) Pub. Date: Sep. 10, 2026

(54) SPIN-DRY CHAMBER FOR CLEANING VARIOUS SIZED SUBSTRATES

(71) Applicant: Applied Materials, Inc., Santa Clara, CA (US)

(72) Inventor: Jason A. RYE, Kalispell, MT (US)

(21) Appl. No.: 19/073,889

(22) Filed: Mar. 7, 2025

(51) Int. Cl. H01L 21/67; H01L 21/687

(52) U.S. Cl. CPC H10P 72/0408; H10P 72/0414; H10P 72/7618

(57) ABSTRACT

Embodiments of the present disclosure generally relate to apparatus and methods for cleaning substrates, and to an integrated clean and dry module which may be used to clean substrates having different sizes. In one or more embodiments, a processing chamber includes an enclosure defining a processing volume. A process rotor is disposed within the processing volume. The process rotor is configured to rotate and to move between a lowered position and a raised position. The process rotor includes a plurality of inner pins having a first height and a plurality of outer pins having a second height. The second height is greater than the first height. One or more sweep arms having a nozzle mechanism are configured to apply a fluid onto a first substrate supported by the plurality of inner pins or a second substrate supported by the plurality of outer pins. A rotor cover surrounds the process rotor.

### BACKGROUND

### Field

Embodiments of the present disclosure generally relate to apparatus and methods for cleaning substrates, and, more particularly, to an integrated clean and dry module which may be used to clean substrates having different sizes.

### Description of the Related Art

The cleaning of semiconductor substrates is required during the formation of integrated circuits and microelectronics, as even the smallest contaminants can significantly impact the performance and reliability of the final product. Spin-dry cleaning chambers have been developed as an effective solution. These chambers utilize centrifugal force to remove particles, liquids, and residues from the surface of semiconductor substrates, offering a fast and efficient way to ensure cleanliness without the risk of contamination from cleaning agents or static buildup. Integrated cleaning and drying (ICD) chambers are spin-dry cleaning chambers that are a part of a larger substrate processing cluster tool. During the processing of a substrate, the substrate is transferred to the ICD chamber for a cleaning process.

Spin dry chambers include a plurality of support pins in order to support the substrate during the cleaning process. The support pins include stand-off pins which are used to support the substrate during the loading and unloading process, and grip pins which secure the substrate during the cleaning process. However, support pins are configured to support substrates having the same diameter. Thus, different spin dry chambers are needed for different sized substrates.

Therefore, there is a need in the art for a spin dry chamber that is able to support and clean substrates having different sizes.

### SUMMARY

Embodiments of the present disclosure generally relate to apparatus and methods for cleaning substrates, and, more particularly, to an integrated clean and dry module which may be used to clean substrates having different sizes.

In one or more embodiments, a processing chamber includes an enclosure defining a processing volume. A process rotor is disposed within the processing volume. The process rotor is configured to rotate and to move between a lowered position and a raised position. The process rotor includes a plurality of inner pins having a first height and a plurality of outer pins having a second height. The second height is greater than the first height. One or more sweep arms having a nozzle mechanism are configured to apply a fluid onto a first substrate supported by the plurality of inner pins or a second substrate supported by the plurality of outer pins. A rotor cover surrounds the process rotor.

In one or more embodiments, a processing kit includes a process rotor configured to rotate and to move between a lowered position and a raised position. The process rotor includes a plurality of inner pins having a first height and a plurality of outer pins having a second height. The second height is greater than a first height. The processing kit further includes a collection rotor having an uppermost surface. The outer pins are below the uppermost surface when the process rotor is in the lowered position. A rotor cover surrounds the process rotor and the collection rotor.

In one or more embodiments, a process rotor includes a plurality of inner stand-off pins disposed at a first radial distance from a center of the process rotor. A plurality of inner grip pins are disposed at the first radial distance from the center of the process rotor. The inner stand-off pins and the inner grip pins have a first height. A plurality of outer grip pins are disposed at a second radial distance from the center of the process rotor. The second radial distance is greater than the first radial distance. The process rotor further includes a plurality of outer stand-off pins. One or more outer stand-off pins are disposed at a third distance from the center of the process rotor. A third radial distance is greater than the first radial distance and less than or equal to the second radial distance. The outer stand-off pins and the outer grip pins have a second height greater than the first height.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic side cross sectional view of a processing chamber, according to one or more embodiments.

FIGS. 2A and 2B are detailed cross-sectional views of a portion of the processing chamber 100 showing an exemplary configuration of a grip pin, according to one or more embodiments.

FIG. 3A is a top schematic isometric view of the processing chamber with the enclosure omitted, according to one or more embodiments.

FIG. 3B is a schematic isometric view of the process rotor, according to one or more embodiments.

FIG. 3C is a zoomed in schematic isometric view of the process rotor, according to one or more embodiments.

FIG. 4A is a schematic top view of the process rotor, according to one or more embodiments.

FIG. 4B is a schematic top view of the process rotor supporting a first substrate, according to one or more embodiments.

FIG. 4C is a schematic top view of the process rotor supporting a second substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatus and methods for cleaning substrates, and, more particularly, to an integrated clean and dry module which may be used to clean substrates having different sizes. In one or more embodiment, a processing chamber includes a process rotor with inner pins and outer pins. The inner pins include a plurality of inner stand-off pins and a plurality of inner grip pins. The inner pins are configured to support a first substrate having a first diameter. The outer pins include a plurality of outer stand-off pins and a plurality of outer grip pins. The outer pins are configured to support a second substrate having a second diameter greater than the first diameter. The process rotor having both inner pins and outer pins allows for the process rotor to process substrates having different sizes.

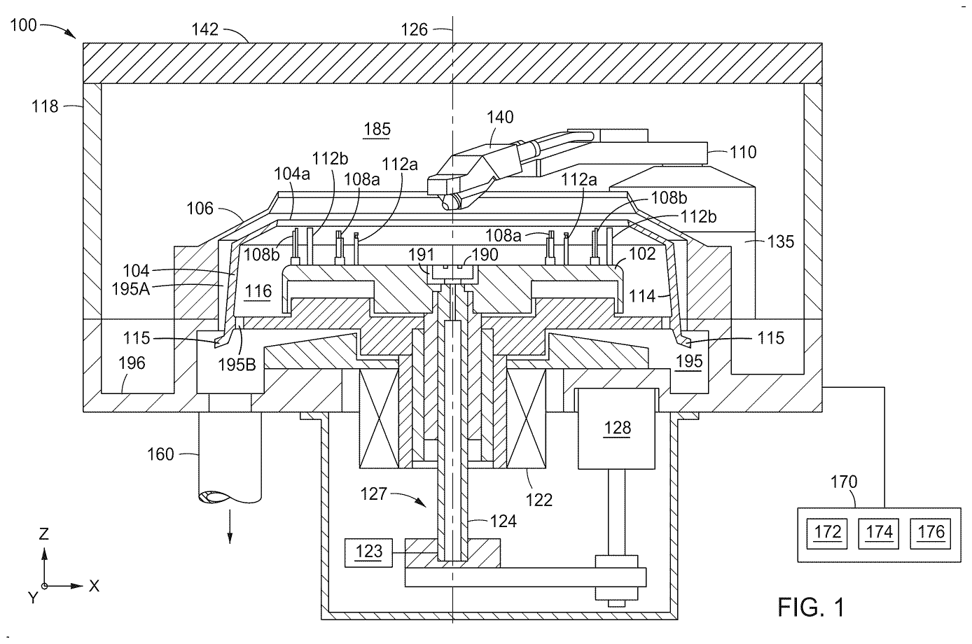

FIG. 1 is a schematic side cross sectional view of a processing chamber 100 according to one or more embodiments. In one or more embodiments, the processing chamber 100 is an exemplary spin dry chamber. During a processing operation, the processing chamber 100 receives a substrate to be subject to a final clean and dry process after the substrate has been cleaned within one or more of the modules of a cluster tool (not shown). The processing chamber 100 may be utilized to remove contamination from the substrate that if not removed, may result in the substrate not meeting contamination and defect requirements. The processing chamber 100 may also be utilized to remove residual moisture from the substrate that, if not removed, may lead to subsequent re-contamination of the substrate when the substrate is subject to further processing.

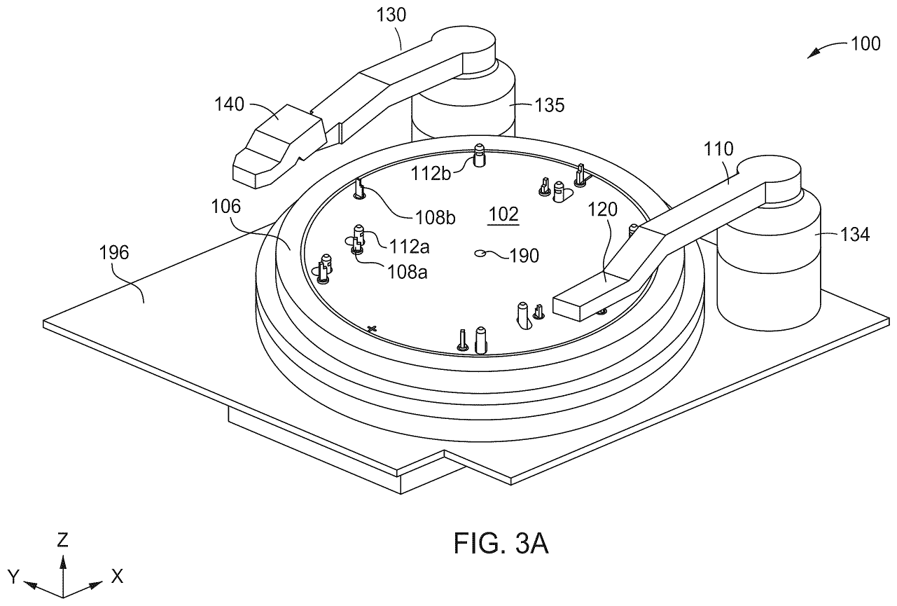

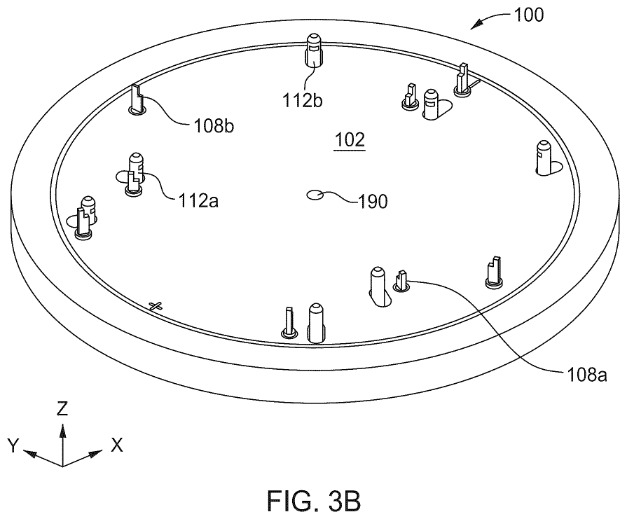

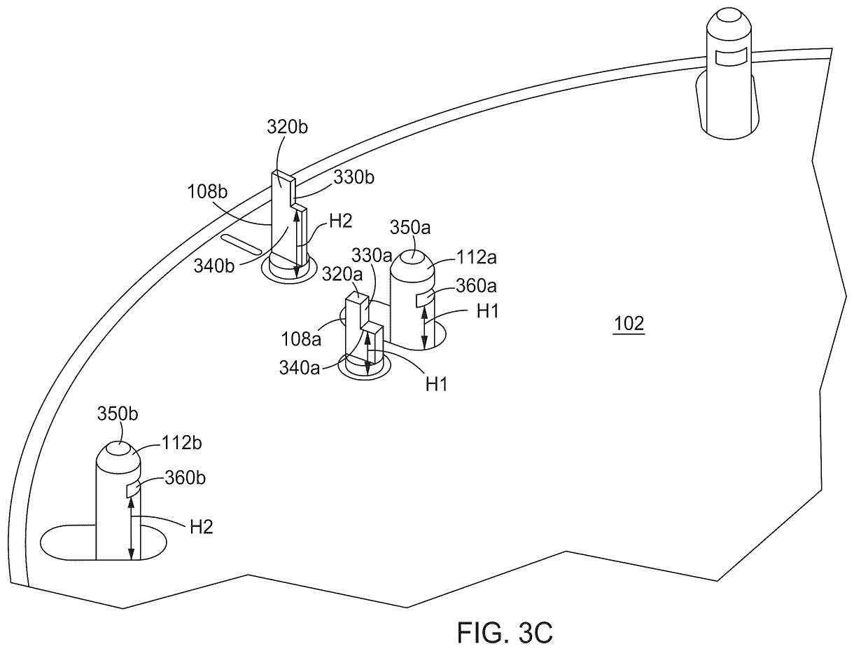

The processing chamber 100 includes a process rotor 102, a collection rotor 104, a rotor cover 106, a first sweep arm 110 (FIG. 3A), an enclosure 118, a first nozzle mechanism 120 (FIG. 3A), a second sweep arm 130, a second nozzle mechanism 140, a primary exhaust 160, and an underside nozzle mechanism 190. In one or more embodiments, a controller 170 may control the functionality of the processing chamber 100.

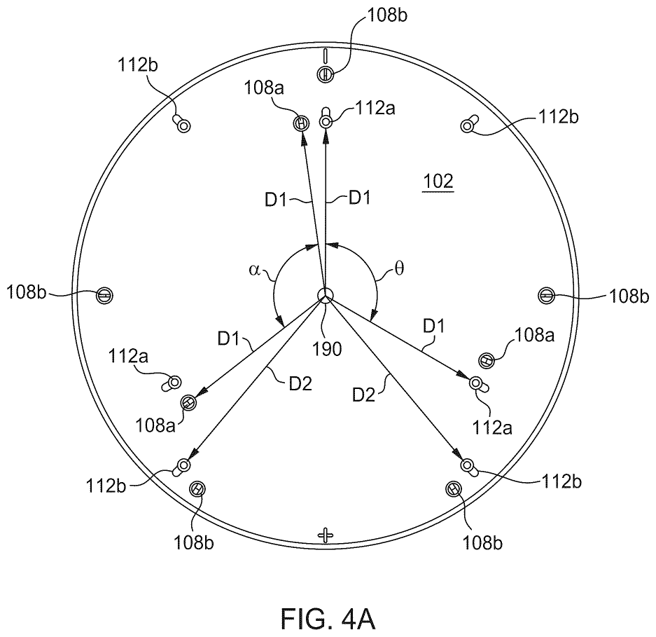

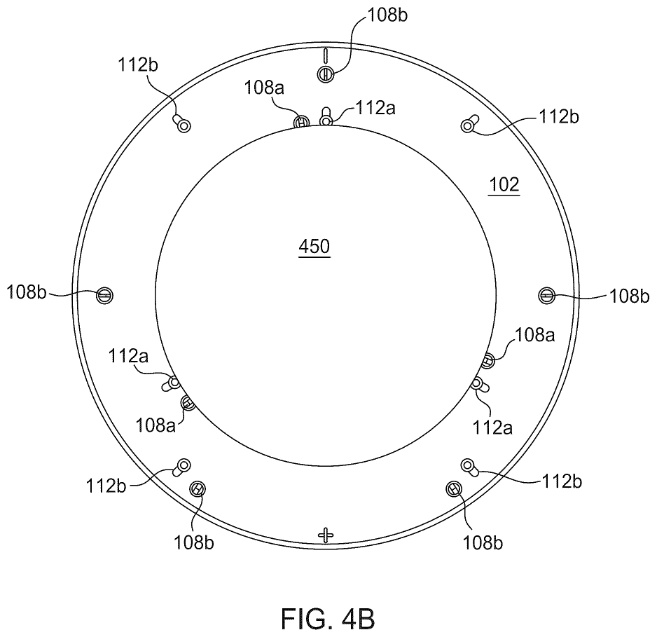

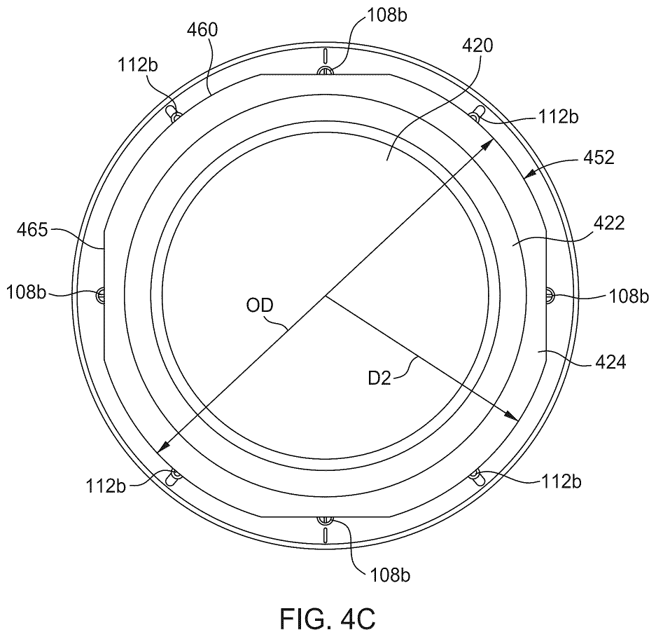

The process rotor 102 includes a plurality of stand-off pins 108a, 108b extending from a top surface thereof. The stand-off pins 108a, 108b include a plurality of inner stand-off pins 108a and a plurality of outer stand-off pins 108b. The inner stand-off pins 108a are configured to support a first substrate 450 (FIG. 4B) that is delivered to the processing chamber 100 by a substrate handler such as, for example, a robot arm. In one or more embodiments the first substrate 450 is a semi-conductor substrate. In one or more embodiments, the first substrate 450 has an outer diameter of about 300 mm. The outer stand-off pins 108b are configured to support a second substrate 452 (FIG. 4C) that is delivered to the processing chamber 100 by a substrate handler such as, for example, a robot arm. In one or more embodiments, the second substrate 452 is a substrate mounted to a film frame carrier. In one or more embodiments, the second substrate 452 has an outer diameter of about 400 mm. The stand-off pins 108a, 108b may have an “L” shaped upper profile to support the substrate and to ensure the substrate is centrally positioned on the process rotor 102. The stand-off pins 108a, 108b may also have a minimal cross-section so as to have minimal contact points with the substrate being supported. In one or more embodiments the outer stand-off pins 108b have a greater height than the inner stand-off pins 108a. The height of the outer stand-off pins 108b is from about 5 mm to about 10 mm, such as about 8 mm greater than the height of the inner stand-off pins 108a.

The process rotor 102 also includes a plurality of grip pins 112a, 112b. The grip pins 112a, 112b include a plurality of inner grip pins 112a and a plurality of outer grip pins 112b. The inner grip pins 112a are configured to support a first substrate 450 (FIG. 4B) that is delivered to the processing chamber 100 by a substrate handler such as, for example, a robot arm. The outer grip pins 112b are configured to support a second substrate 452 (FIG. 4C) that is delivered to the processing chamber 100 by a substrate handler such as, for example, a robot arm. In one or more embodiments the outer grip pins 112b have a greater height than the inner grip pins 112a. The height of the outer grip pins 112b is from about 5 mm to about 10 mm, such as about 8 mm greater than the height of the inner grip pins 112a.

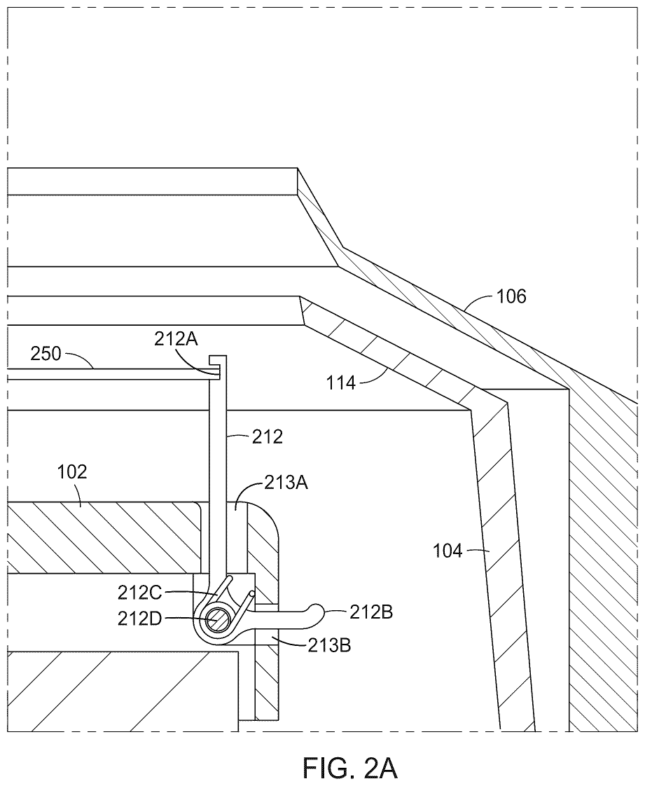

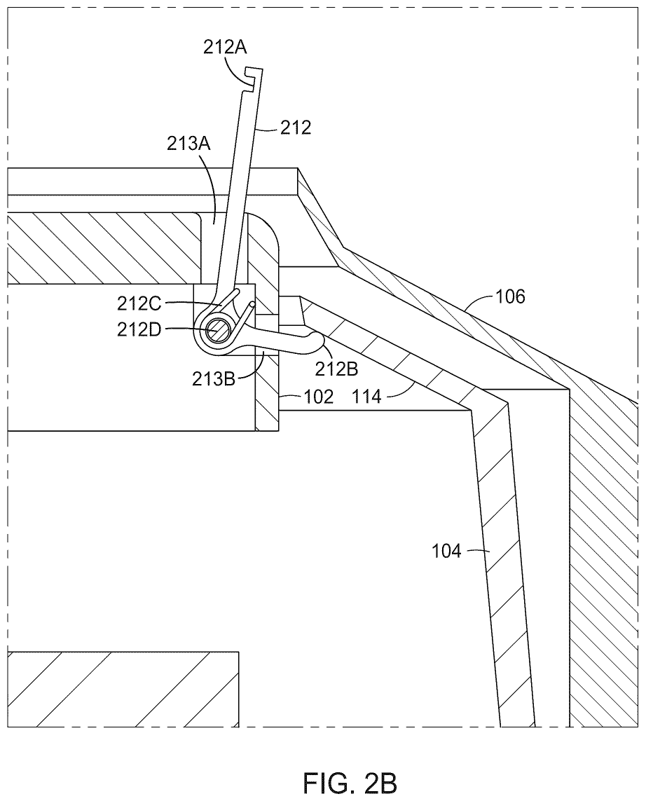

FIGS. 2A and 2B are detailed cross-sectional views of a portion of the processing chamber 100 showing an exemplary configuration of a grip pin 212, according to one or more embodiments. The grip pin 212 can be any of the grip pins described herein, including any of the inner grip pins 112a or any of the outer grip pins 112b. As illustrated in FIGS. 2A and 2B, the grip pin 212 extends from a hole 213A in the top surface of the process rotor 102. A protruding element 212B extends from a lower portion of the grip pin 212 through a hole 213B in a side surface of the process rotor 102. According to embodiments, the grip pin 212 is movable between a grip position (shown in FIG. 2A) and a release position (shown in FIG. 2B). For example, the grip pin 212 may pivot about a grip pin axis 212D between the grip position and the release position. In the grip position shown in FIG. 2A, the upper portion of each grip pin 212 is positioned to grip the outer circumference of a substrate 250. The substrate 250 can be any of the substrates described herein, including the first substrate 450 or the second substrate 452. In the release position shown in FIG. 2B, an upper portion of each grip pin 212 is positioned beyond an outer circumference of the substrate 250 so that the substrate 250 can be received on the process rotor 102, i.e., on the outer stand-off pins 108b or the inner stand-off pins 108a (or removed from the process rotor 102). The grip pins 212 may be biased towards the grip position by, for example, spring 212C. The grip pins 212 may also include a shaped area configured to receive the substrate 250. For example, each grip pin 212 may include a notch 212A shaped to receive an edge of the substrate 250.

Referring to FIG. 1, the grip pins 112a, 112b may grip, or hold, the substrate during the cleaning process. The process rotor 102 is movable between a raised position and a lowered position by use of a lift assembly 127 that includes a second drive motor 128 and a shaft 124. In FIGS. 1 and 2A, the process rotor 102 is shown in the lowered position, and in FIG. 2B, the process rotor 102 is shown in the raised position. In the raised position, the process rotor 102 can receive a substrate, as the stand-off pins 108a, 108b and the grip pins 112a, 112b are above a top portion of the collection rotor 104 and the rotor cover 106. As can be seen in FIG. 2B, the protruding element 212B is configured to contact an annular inner surface 114 of the collection rotor 104 when the process rotor 102 is moved towards the raised position. As the process rotor 102 continues to move to the raised position, the annular inner surface 114 applies pressure to the protruding element 212B, which overcomes the biasing force of the spring 212C and imparts an outward rotational motion onto one or more of the grip pins 212, thereby moving the grip pins to the release position. Similarly, when the process rotor 102 is moved to the lowered position, the protruding element 212B of each grip pin 212 no longer contacts the surface 114 of the collection rotor 104, and the grip pins 212 rotate to the grip position that causes the substrate to be retained between the grip pins 212. The lowered position is also referred to herein as the processing position at which the clean and drying process is performed.

Referring back to FIG. 1, the collection rotor 104 includes an annular inner surface 114. The annular inner surface 114 defines a processing volume 116 within the processing chamber 100. For example, the substrate may be cleaned within the processing volume 116. Further, the annular inner surface 114 has an angled portion that is symmetric about a rotational axis 126 of the process rotor 102 and the collection rotor 104. When the processing chamber 100 is in the lowered position, the inner stand-off pins 108a, the outer stand-off pins 108b, the inner grip pins 112a, and the outer grip pins 112b are positioned below an uppermost surface 104a of the collection rotor 104.

A first drive motor 122 may be coupled to the process rotor 102 via the shaft 124. The first drive motor 122 rotates the process rotor 102 and the collection rotor 104 about the rotational axis 126. That is, the controller 170 may control the first drive motor 122 to rotate the process rotor 102 and the collection rotor 104 at various rotational speeds set by process recipes contained in the memory 174 of the controller 170. The first drive motor 122 may be referred to as a rotation motor. The process rotor 102 and the collection rotor 104 may be rotationally fixed relative to each other, i.e., configured to rotate together.

Further, the second drive motor 128 may also be coupled to the process rotor 102 via the shaft 124. The second drive motor 128 may impart linear motion to the process rotor 102 along the rotational axis 126 by use of a ball-screw assembly that is configured to create linear motion of the process rotor 102 due to relative rotational motion created by the second drive motor 128 rotating the shaft 124 relative to a portion of the collection rotor 104. That is, the controller 170 may control the second drive motor 128 to move the process rotor 102 in the Z direction between the raised position and lowered position. In addition, the second drive motor 128 may be used to move the process rotor 102 in the Z direction in preparation for, or during, a cleaning, rinsing, and/or drying process to precisely position a substrate at a desired radial from first and second nozzle mechanisms 120, 140 or position relative to the surface of the collection rotor 104. Thus, the second drive motor 128 may be configured to move the process rotor 102 in the Z direction while the process rotor 102 is spinning and/or while a substrate is being subject to cleaning, rinsing, and/or drying. The second drive motor 128 may be referred to as a linear actuator. Further, the second drive motor 128 may be one of a hydraulic, pneumatic, electro-mechanical, and a magnetic motor. The linear movement of the process rotor 102 may be independent of movement of the collection rotor 104.

The grip pins 112a, 112b hold the substrate when the process rotor 102 is in the lowered position, as described above. When the process rotor 102 is in the lowered position, the first drive motor 122 may rotate the process rotor 102 while cleaning fluids are applied to the substrate for cleaning. Cleaning fluids may be applied to an upper surface of the substrate by the first nozzle mechanism 120 and the second nozzle mechanism 140, and to a lower surface of a substrate via an underside nozzle mechanism 190, while the process rotor 102 and the collection rotor 104 are rotated. Because the collection rotor 104 is rotated with the process rotor 102, backsplash of the cleaning fluids against the inner surface 114 may be mitigated.

Cleaning and/or rinsing fluids may be delivered to the underside nozzle mechanism 190 via shaft 124, which is coupled to a fluid source 123. In one or more embodiments, cleaning and/or rinsing fluids may flow onto a backside of a substrate through the underside nozzle mechanism 190. The cleaning and/or rinsing fluids may be a rinsing agent (e.g., de-ionized water or ozonated water) or a cleaning chemical. Further, the cleaning and/or rinsing fluids may be provided from the fluid source to the underside nozzle mechanism 190 via the shaft 124.

The process rotor 102 may include a drain 191 adjacent the underside nozzle mechanism 190 to allow fluid applied to the backside of a substrate to drain (described below). According to embodiments, the drain 191 may be an annulus arranged circumferentially around underside nozzle mechanism 190. The drain 191 feeds through the shaft 124 to an aspirate connection (not shown), which may apply a negative pressure to the drain 191 to ensure complete drainage of fluid.

A first sweep arm drive motor 134 (FIG. 3A) may be coupled to the first sweep arm 110. The first sweep arm drive motor 134 is configured to move the first sweep arm 110 in an arcuate path that is parallel to a surface of a substrate, during the cleaning process, such that the cleaning fluids output by the first nozzle mechanism 120 are evenly distributed over the surface of the substrate. The first sweep arm drive motor 134 may also be configured to move the first sweep arm 110 axially to set a distance between the first nozzle mechanism 120 and the surface of a substrate. For example, the first sweep arm drive motor 134 may include an air cylinder for raising and lowering the first nozzle mechanism 120.

Similarly, a second sweep arm drive motor 135 may be coupled to the second sweep arm 130. The second sweep arm drive motor 135 is configured to move the second sweep arm 130 in an arcuate path that is parallel to a surface of a substrate, during the cleaning process, such that the cleaning fluids output by the second nozzle mechanism 140 are evenly distributed over the surface of the substrate. The second sweep arm drive motor 135 may also be configured to move the second sweep arm 130 axially to set a distance between the second nozzle mechanism 140 and the surface of the substrate. For example, the second sweep arm drive motor 135 may include an air cylinder for raising and lowering the second nozzle mechanism 140.

The first and second sweep arms 110, 130 may each include one or more tubes to deliver fluids to the first and second nozzle mechanisms 120, 140, respectively. According to an embodiment, the first and second sweep arms 110, 130 each include connections for delivering fluids and/or electrical signals (e.g., control signals) to the first and second nozzle mechanisms 120, 140, respectively. For example, water and isopropyl alcohol (IPA) may be separately delivered to the first and second nozzle mechanisms 120, 140 via the connections. For example, the first and second sweep arms 110, 130 may also each include a connection for supplying control signals from the controller 170 to the first and second nozzle mechanisms 120, 140, respectively.

The first and second nozzle mechanisms 120, 140 may each include one or more non-contact cleaning or drying technologies. Each of the first and second nozzle mechanisms 120, 140 may have one, two, three or more nozzles that each may output a media that is any combination of liquid or gas. One or more of the first and second nozzle mechanisms 120, 140 may be a megasonic nozzle, fluid jet nozzle, mist nozzle, high pressure nozzle, or a kinetic energy nozzle. The megasonic nozzle includes one or more elements, such as a piezoelectric element, configured to alternatively apply compression and rarefraction to the cleaning fluid in an alternating fashion according to a sinusoidal or other pattern to generate a megasonic actuated fluid. For example, the megasonic nozzle may be configured to alternatively applying compression and rarefraction in a sinusoidal pattern at a rate of 950 kHz to generate the megasonic actuated fluid. Alternatively, other frequencies may be used.

According to an embodiment, where one of the first and second nozzle mechanisms 120, 140 is a megasonic nozzle, the other of the first and second nozzle mechanisms 120, 140 may be configured to apply a chemical cleaning agent, a rinsing agent (e.g., deionized (DI) water), and/or a drying agent (e.g., isopropyl alcohol (IPA) vapor). For example, according to the embodiment illustrated in FIG. 3A, the first nozzle mechanism 120 may be a drying nozzle configured to apply a drying agent such as IPA) and/or DI water, and the second nozzle mechanism 140 may be a megasonic nozzle that is configured to provide DI water and megasonic energy to the surface of the substrate during processing. In some configurations, the second nozzle mechanism 140 may also be configured to apply a chemical cleaning agent, a rinsing agent, and/or a drying agent

As noted, the cleaning, rinsing, and/or drying fluids may be provided to the first and second nozzle mechanisms 120, 140 via connections. The number of connections may be based on the number of nozzles within the nozzle mechanism being used and/or the number of different types of cleaning chemical, rinsing agents and/or drying agents utilized by the first and second nozzle mechanisms 120, 140. For example, where the first and second nozzle mechanisms 120, 140 are each configured to output two different cleaning fluids, two different connections may be utilized for each first and second nozzle mechanisms 120, 140. Further, the flow rate of the different cleaning chemistries and/or rinsing agents through different nozzles may be varied. For example, the flow rate of a cleaning chemical, rinsing agent or drying agent from a first one of the nozzles may be different than the flow rate of a cleaning chemical, rinsing agent or drying agent from a second one of the nozzles. Alternatively, the flow rate of a cleaning chemical, rinsing agent or drying agent from at least one of the nozzles may be varied during a cleaning process, a rinsing process, and/or a drying process.

The first and second sweep arms 110, 130 may include a coupling arrangement for fastening the first and second nozzle mechanisms 120, 140 thereto, respectively. According to embodiments, the coupling arrangement between the first and second nozzle mechanisms 120, 140 and the first and second sweep arms 110, 130 may be an industry standard coupling arrangement, and one or both of the first and second nozzle mechanisms 120, 140 may be commercially available nozzles. Each nozzle mechanism 120, 140 can be readily replaced as needed depending on a desired application or for repair and/or routine maintenance.

The path of the first and second sweep arms 110, 130 during a cleaning process may be an arcuate path that is parallel to a front surface of a substrate. Alternatively, other shapes and/or lengths of paths may be utilized. For example, the range of motion of the first and second sweep arms 110, 130 may be varied. According to some embodiments, the first and second nozzle mechanisms 120, 140 respectively coupled to the end of first and second sweep arms 110, 130 may pass over the center of a substrate in an arcuate path. The position of the first and second sweep arms 110, 130 and/or the first and second nozzle mechanisms 120, 140 may be adjusted to ensure that the first and second nozzle mechanisms 120, 140 pass over the center of a rotating substrate during processing. Further, the nozzle mechanisms 120, 140 may be moved relative to the corresponding first and second sweep arms 110, 130 to vary the position of the first and second nozzle mechanisms 120, 140 relative to surface of a substrate. Further, the axial distance between first and second nozzle mechanisms 120, 140 and the surface of the substrate may be varied to aid in the cleaning process.

The first and second nozzle mechanisms 120, 140 may include a mass flow controller to provide mass flow control of fluids being sprayed on the substrate, depending on a desired cleaning, rinsing, and/or drying process. The nozzle mechanisms 120, 140 may also include a vaporizer for vaporizing IPA or water being sprayed on the substrate, depending on a desired cleaning, rinsing and/or drying process. The nozzle mechanisms 120, 140 may also be configured to blow air only, depending on a desired cleaning process. For example, the cleaning, rinsing, and/or drying process may optionally include a cycle in which one or both of the nozzle mechanisms 120, 140 blow air to dry the stand-off pins 108a, 108b and/or the grip pins 112a, 112b.

Referring to FIG. 1, the enclosure 118 may cover the processing chamber 100, i.e., defining an interior volume 185 of the processing chamber 100. Alternatively, the processing chamber 100 may be “open” to the rest of the cluster tool, i.e., the process chamber alternatively does not include an enclosure 118. In such an alternative embodiment, the face of the substrate is exposed to atmosphere while being processed within the processing chamber 100.

The primary exhaust 160 may be utilized to remove excess moisture and/or all fluids from the processing chamber 100 during and/or after a cleaning cycle. In one embodiment, moisture flows through drain holes 195B and into the primary exhaust 160. For example, as the substrate is rotated, the drain holes 195B are configured to ensure that moisture does not collect on the substrate and is removed via the primary exhaust 160. In one embodiment, one or more O-rings or other sealing members may be positioned where the primary exhaust 160 meets the enclosure 118. The process chamber may have two primary exhausts 160, one on each lateral side of the processing chamber 100.

An annular collection weir 195 may be formed below an outer portion of the collection rotor 104. The primary exhaust 160 is connected to the collection weir 195. An annular space 195A is defined between an outer surface of the collection rotor 104 and an inner surface of the rotor cover 106. According to embodiments, this configuration may allow for a high volume of laminar air flow through the annular space 195A between the rotor cover 106 and the collection rotor 104, which may reduce the amount of residual vapors and liquid droplets created during processing and disposed within this region, and thus reduce substrate contamination and improve the cleaning process. Additionally, any liquid that may inadvertently be introduced into the annular space 195A can drain out the primary exhaust 160, assisted by the air flow through the annular space 195A.

A plurality of drain holes 195B may be formed in a base of the collection rotor 104. For example, according to embodiments, the drain holes 195B may be formed near the annular inner surface 114 of the collection rotor 104. The drain holes 195B allow fluids applied during a cleaning process of a substrate to drain out of the collection rotor 104 and into the collection weir 195. According to an embodiment, the annular inner surface 114 of the collection rotor 104 includes a portion angled inward with respect to vertical from a lower portion to an upper portion. This configuration may improve fluid drainage from the processing volume 116 due to rotation of the collection rotor 104. According to some embodiments, the plurality of drain holes 195B are configured to enable a laminar flow of air to flow over the surface of a substrate and through the inner region of the collection rotor 104 and drain holes 195B to reduce the amount of residual vapors and liquid droplets created during processing and disposed within this region, and thus reduce substrate contamination and improve the cleaning process. According to embodiments, this configuration may provide for a high volume of air flow through the processing volume 116, which may provide for improved cleaning processing.

Additionally, according to some embodiments, the collection rotor 104 may include rotor extension 115 extending diagonally downward and outward from the lower portion of the collection rotor 104. The rotor extension 115 (FIG. 1) may further improve fluid drainage from the processing volume by drawing and guiding the fluids from the drain holes 195B as the collection rotor 104 rotates. The rotor extension 115 is generally configured to extend past the outer edge of the drain holes 195B and past the outer diameter of the collection rotor at the level of the drain holes 195B.

The controller 170, such as a programmable computer, is connected to elements of processing chamber 100 and is configured to operate the elements of the processing chamber 100. For example, the controller 170 may control the loading, unloading and cleaning of substrates by the processing chamber 100.

The controller 170 is one or more of any form of a general-purpose computer processor that is used in an industrial setting for controlling various substrate processing chambers and equipment, and sub-processors thereon or therein. The memory 174, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 176 of the controller 170 are coupled to the CPU 172 for supporting the CPU 172. The support circuits 176 include cache, power supplies, clock circuits, input/output circuitry and subsystems, and the like. Operational parameters and operations are stored in the memory 174 as a software routine that is executed or invoked to turn the controller 170 into a specific purpose controller to control the operations of the various chambers/modules described herein The controller 170 and the processing chamber 100 are at least part of a system for processing substrates.

FIG. 3A is a top schematic isometric view of the processing chamber 100 with the enclosure 118 omitted, according to one or more embodiments. It is intended that all cleaning liquids applied during a cleaning processing are contained within the rotor cover 106 and drained through the primary exhaust 160 and/or the secondary exhaust. 170 (FIG. 1). However, cleaning liquids may inadvertently leak outside of the collection rotor and the rotor cover 106 due to, for example, failure or defect in one or more components. Accordingly, to prevent contamination of the exterior of the processing chamber 100 in case of an inadvertent leak, a chamber bottom 196 is provided surrounding the perimeter of the rotor cover 106.

FIG. 3B is a schematic isometric view of the process rotor, according to one or more embodiments. FIG. 3C is a zoomed in schematic isometric view of the process rotor 102, according to one or more embodiments. The process rotor 102 includes the inner stand-off pins 108a, the inner grip pins 112a, the outer stand-off pins 108b and the outer grip pins 112b. The stand-off pins 108a, 108b each include an uppermost surface 320a, 320b, an inner sidewall 330a, 330b, and a support surface 340a, 340b. The support surface 340a of the inner stand-off pins 108a are configured to support the first substrate 450. A first height H1 is defined by the distance between the distance between the support surface 340a of the inner stand-off pins 108a and the top surface of the process rotor 102. The support surface 340b of the outer stand-off pins 108b are configured to support the second substrate 452. A second height H2 is defined by the distance between the distance between the support surface 340b of the outer stand-off pins 108b and the top surface of the process rotor 102.

The grip pins 112a, 112b each include an uppermost surface 350a, 350b and a notch 360a, 360b. The lower surface within the notch 360a of the inner grip pins 112a is configured to support the first substrate 450. The first height H1 is defined by the distance between the lower surface within the notch 360a of the inner grip pins 112a and the top surface of the process rotor 102. The support surface 340b of the outer stand-off pins 108b are configured to support the second substrate 452. A second height H2 is defined by the distance the lower surface within the notch 360b of the outer grip pins 112b and the top surface of the process rotor 102. The second height H2 is greater than the first height H1. In one or more embodiments, the second height H2 is from about 5 mm greater to about 10 mm greater, such as about 8 mm greater than the first height H1. In one or more embodiments, the second height H2 is greater than the distance between the uppermost surface 350a of the inner grip pins 112a and the upper surface of the process rotor 102. In one or more embodiments, the second height H2 is greater than the distance between the uppermost surface 320a of the inner stand-off pins 108a and the upper surface of the process rotor 102. In one or more embodiments the distance between the uppermost surface 104a of the collection rotor (FIG. 1) and the upper surface of the process rotor 102 is greater than the distance between the uppermost surface 350b of the outer grip pins 112b and the upper surface of the process rotor 102. In one or more embodiments the distance between the uppermost surface 104a of the collection rotor (FIG. 1) and the upper surface of the process rotor 102 is greater than the distance between the uppermost surface 320b of the outer stand-off pins 108b and the upper surface of the process rotor 102.

FIG. 4A is a schematic top view of the process rotor 102, according to one or more embodiments. The process rotor 102 includes a plurality of inner stand-off pins 108a, a plurality of outer stand-off pins 108b, a plurality of inner grip pins 112a, and a plurality of outer grip pins 112b. The center of the process rotor 102 is axially aligned with the rotational axis 126 (FIG. 1). In one or more embodiments, the plurality of inner stand-off pins 108a, the plurality of outer stand-off pins 108b, the plurality of inner grip pins 112a, and the plurality of outer grip pins 112b are axially aligned with the rotational axis 126. In one or more embodiments, the plurality of inner grip pins 112a and the plurality of inner stand-off pins 108a are disposed on the process rotor 102 at a first radial distance D1 from the center of the process rotor 102. The first radial distance is about 150 mm. In one or more embodiments, the plurality of inner stand-off pins 108a may be evenly arranged around the top surface of the process rotor 102 at an angle α relative to one another. For example, if the plurality of inner stand-off pins 108a includes 3 inner stand-off pins 108a, then the angle α, that is, the angular position of the inner stand-off pins 108a from each other, may be approximately 120°. If the plurality of inner stand-off pins 108a includes 4 inner stand-off pins 108a, then the angle α, that is, the angular position of the inner stand-off pins 108a from each other, may be approximately 90°. In one or more embodiments, the plurality of inner grip pins 112a may be evenly arranged around the top surface of the process rotor 102 at an angle θ relative to one another. For example, if the plurality of inner grip pins 112a includes 3 inner grip pins 112a, then the angle θ, that is, the angular position of the inner grip pins 112a from each other, may be approximately 120°. If the plurality of inner grip pins 112a includes 4 inner grip pins 112a, then the angle θ, that is, the angular position of the inner grip pins 112a from each other, may be approximately 90°.

Although FIG. 4A shows the process rotor 102 including 3 inner grip pins 112a and 3 inner stand-off pins 108a, it is contemplated that the process rotor 102 may include any number of inner grip pins 112a and inner stand-off pins 108a. The number of inner grip pins 112a and inner stand-off pins 108a may be the same as one another or different from one another. The inner grip pins 112a and the inner stand-off pins 108a are configured to support a first substrate 450 having a diameter of about 300 mm. The inner grip pins 112a and the inner stand-off pins 108a have a first height.

In one or more embodiments the plurality of outer grip pins 112b are disposed on the process rotor 102 at a second radial distance D2 from the center of the process rotor 102. The second radial distance D2 is about 200 mm. The outer grip pins 112b may or may not be evenly arranged around the top surface of the process rotor 102. Each of the outer stand-off pins 108b are disposed on the process rotor 102 at a distance from the center of the process rotor 102 that is less than or equal to the second radial distance D2. The outer stand-off pins 108b may be disposed at the same distance from the center of the process rotor 102 as one another. In one or more embodiments, one or more of the outer stand-off pins 108b are disposed at a different distance from the center of the process rotor 102 as one another.

Although FIG. 4A shows the process rotor 102 including 4 outer grip pins 112b and 5 outer stand-off pins 108b, it is contemplated that the process rotor 102 may include any number of outer grip pins 112b and outer stand-off pins 108b. The number of outer grip pins 112b and outer stand-off pins 108b may be the same as one another or different from one another. The outer grip pins 112b and the outer stand-off pins 108b are configured to support a second substrate 452 having an outer diameter of about 400 mm. The outer grip pins 112b and the outer stand-off pins 108b have a second height. The second height is greater than the first height. In one or more embodiments, the second height is from about 5 mm to about 10 mm, such as about 8 mm greater than the first height.

FIG. 4B is a schematic top view of the process rotor 102 supporting a first substrate 450, according to one or more embodiments. The process rotor 102 of FIG. 4B is shown in the lowered position. During a loading operation the first substrate 450 is disposed on the inner stand-off pins 108a when the process rotor is in the raised position. The process rotor 102 is then lowered into the lowered position and the inner grip pins 112a grip the substrate 450 as described in FIGS. 2A and 2B. The inner stand-off pins 108a and the inner grip pins 112a support the substrate during a processing operation. The first substrate has a diameter of about 300 mm. In one or more embodiments the first substrate 450 is a semi-conductor substrate.

FIG. 4C is a schematic top view of the process rotor 102 supporting a second substrate 452, according to one or more embodiments. The process rotor 102 of FIG. 4B is shown in the lowered position. In one or more embodiments the second substrate 452 includes a substrate 420, an adhesive tape 422, and a film frame 424. The substrate 420 has an outer diameter. The film frame 424 has an inner diameter greater than the outer diameter of the substrate 420. The substrate 420 coupled to the film frame 424 using the adhesive tape 422. The substrate 420 and the film frame 424 are concentric to the center of the process rotor 102. The film frame 424 surrounds the substrate 420. In one or more embodiments the film frame 424 includes one or more curved outer edges 460 and one or more flat outer edges 465. In one or more embodiments, the curved outer edges 460 are located at the second radial distance D2 from the center of the process rotor 102. The curved outer edges 460 define an outer diameter OD of the film frame 424. The flat outer edges 465 are positioned inward from the outer diameter OD. During a loading operation, the second substrate 452 is disposed on the outer stand-off pins 108b when the process rotor is in the raised position. In one or more embodiments, the outer stand-off pins 108b contact the flat outer edges 465 of the film frame 424. The process rotor 102 is then lowered into the lowered position and the outer grip pins 112b grip the second substrate 452 as described in FIGS. 2A and 2B. The outer stand-off pins 108b and the outer grip pins 112b support the second substrate 452 during a processing operation. The outer stand-off pins 108b and the outer grip pins 112b support second substrate 452 above the inner grip pins 112a and the inner stand-off pins 108a so that the second substrate 452 does not contact the inner grip pins 112a or the inner stand-off pins 108a during a processing operation.

Benefits of the present disclosure include a processing chamber that is configured to perform a cleaning process on different sized substrates. Having a single processing chamber that can clean different types of substrates, which allows for increased substrate processing, decreased chamber footprint, decreased cost, decreased maintenance, and improved device quality.

It is contemplated that one or more aspects disclosed herein may be combined. As an example, one or more aspects, features, components, operations and/or properties of the processing chamber 100, the process rotor 102, the collection rotor 104, the rotor cover 106, the first sweep arm 110, the second sweep arm 130, the inner stand-off pins 108a, the outer stand-off pins 108b, the inner grip pins 112a, the outer grip pins 112b, the grip pin 212, the first substrate 450, the second substrate 452, the substrate 420, the adhesive tape 422, and/or the film frame 424 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
an enclosure defining a processing volume;
a process rotor disposed within the processing volume, the process rotor being configured to rotate and to move between a lowered position and a raised position, the process rotor comprising:
a plurality of inner pins having a first height, and
a plurality of outer pins having a second height, wherein the second height is greater than the first height;
one or more sweep arms having a nozzle mechanism configured to apply a fluid onto a first substrate supported by the plurality of inner pins or a second substrate supported by the plurality of outer pins; and
a rotor cover surrounding the process rotor.

2. The processing chamber of claim 1, wherein the plurality of inner pins comprise a plurality of inner grip pins and a plurality of inner stand-off pins.

3. The processing chamber of claim 2, wherein the plurality of inner stand-off pins include an uppermost surface and a support surface, wherein the support surface is configured to support the first substrate.

4. The processing chamber of claim 3, wherein the first substrate has an outer diameter of about 300 mm.

5. The processing chamber of claim 1, wherein the plurality of inner pins are disposed at a first radial distance from a center of the process rotor.

6. The processing chamber of claim 1, wherein the plurality of outer pins comprise a plurality of outer grip pins and a plurality of outer stand-off pins.

7. The processing chamber of claim 6, wherein the plurality of outer stand-off pins include an uppermost surface and a support surface, wherein the support surface is configured to support the second substrate.

8. The processing chamber of claim 7, wherein the second substrate has an outer diameter of about 400 mm.

9. The processing chamber of claim 6, wherein the plurality of outer grip pins are disposed at a second radial distance from a center of the process rotor and one or more outer stand-off pins are disposed at a third distance from the center of the process rotor, wherein a third radial distance is less than or equal to the second radial distance.

10. The processing chamber of claim 1, wherein the second height is from about 5 mm greater to about 10 mm greater than the first height.

11. A processing kit, comprising:
a process rotor configured to rotate and to move between a lowered position and a raised position, the process rotor comprising:
a plurality of inner pins having a first height, and
a plurality of outer pins having a second height, wherein the second height is greater than a first height;
a collection rotor having an uppermost surface, wherein the outer pins are below the uppermost surface when the process rotor is in the lowered position; and
a rotor cover surrounding the process rotor and the collection rotor.

12. The processing kit of claim 11, wherein the plurality of inner pins comprise a plurality of inner grip pins and a plurality of inner stand-off pins.

13. The processing kit of claim 12, wherein the plurality of inner stand-off pins include an uppermost surface and a support surface, wherein the support surface is configured to support a first substrate having a diameter of about 300 mm.

14. The processing kit of claim 11, wherein the plurality of inner pins disposed at a first radial distance from a center of the process rotor.

15. The processing kit of claim 11, wherein the plurality of outer pins comprise a plurality of outer grip pins and a plurality of outer stand-off pins.

16. The processing kit of claim 15, wherein the plurality of outer stand-off pins include an uppermost surface and a support surface, wherein the support surface is configured to support a second substrate having a diameter of about 400 mm.

17. The processing kit of claim 15, wherein the plurality of outer grip pins are disposed at a second radial distance from a center of the process rotor and one or more outer stand-off pins are disposed at a third distance from the center of the process rotor, wherein a third radial distance is less than or equal to the second radial distance.

18. The processing kit of claim 11, wherein the second height is from about 5 mm greater to about 10 mm greater than a first height.

19. A process rotor, comprising:
a plurality of inner stand-off pins disposed at a first radial distance from a center of the process rotor;
a plurality of inner grip pins disposed at the first radial distance from the center of the process rotor, wherein the inner stand-off pins and the inner grip pins have a first height;
a plurality of outer grip pins disposed at a second radial distance from the center of the process rotor, wherein the second radial distance is greater than the first radial distance; and
a plurality of outer stand-off pins, wherein one or more outer stand-off pins is disposed at a third distance from the center of the process rotor, a third radial distance is greater than the first radial distance and less than or equal to the second radial distance, wherein the outer stand-off pins and the outer grip pins have a second height greater than the first height.

20. The process rotor of claim 19, wherein the second height is from about 5 mm greater to about 10 mm greater than the first height.
